(19) United States
(12) Patent Application Publication
(10) Pub. No.: US 2017/0084326 A1
(43) Pub. Date: Mar. 23, 2017

(54) A NEGATIVE DIFFERENTIAL RESISTANCE BASED MEMORY

(71) Applicants: Daniel H. Morris, Hillsboro, OR (US); Uygar E. Avci, Portland, OR (US); Rafael Rios, Portland, OR (US); Ian A. Young, Portland, OR (US)

(72) Inventors: Daniel H. Morris, Hillsboro, OR (US); Uygar E. Avci, Portland, OR (US); Rafael Rios, Portland, OR (US); Ian A. Young, Portland, OR (US)

(21) Appl. No.: 15/126,255

(22) PCT Filed: Jul. 8, 2014
(86) PCT No.: PCT/US2014/045695

§ 371 Date: Sep. 14, 2016

(51) Int. Cl. G11C 11/38; H01L 27/105; H01L 27/102; G11C 11/412

(52) U.S. Cl. CPC G11C 11/38; G11C 11/412; H01L 27/1052; H01L 27/1021

(57) ABSTRACT

Described is a memory bit-cell comprising: a storage node; an access transistor coupled to the storage node; a capacitor having a first terminal coupled to the storage node; and one or more negative differential resistance devices coupled to the storage node such that the memory bit-cell is without one of a ground line or a supply line or both.

### BACKGROUND

Dense and high performance embedded memory is an essential ingredient for high performance Central Processing Units (CPUs), Graphics Processing Units (GPUs), and System-on-Chips (SoCs). Static Random Access Memory (SRAM) is a commonly used memory, but it is not scaling well to low power supply voltages (e.g., less than 1V) at advanced process nodes. With a cell size one-third that of SRAM bit-cell size, Embedded Dynamic Random Access Memory (EDRAM) is an attractive memory alternative for some applications. However, EDRAM too has challenges since it has to be refreshed regularly (e.g., every 1 ms or less). During refresh, the value of the EDRAM bit-cell is read and rewritten to its full voltage level. Refreshing consumes significant dynamic power and reduces the available bandwidth for read and write operations of the EDRAM array.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a high-level circuit of a negative differential resistance (NDR) device based memory bit-cell, according to one embodiment of the disclosure.

FIG. 2A-C illustrate plots showing I-V characteristics of an NDR diode and associated circuit.

FIG. 3A illustrates an NDR device based memory bit-cell with n-type transistor, according to one embodiment of the disclosure.

FIG. 3B illustrates a top view of layout of NDR device based memory bit-cell with n-type transistor, according to one embodiment of the disclosure.

FIGS. 4A-B illustrate NDR device based memory bit-cells with p-type transistors according to one embodiment of the disclosure.

FIG. 5 illustrates a top view of a layout of the NDR device based memory bit-cell array of FIG. 3A, according to one embodiment of the disclosure.

FIG. 6A illustrates a cross-section of the layout of the NDR device based memory bit-cell of FIG. 3B, according to one embodiment of the disclosure.

FIG. 6B illustrates another cross-section of the layout of the NDR device based memory bit-cell of FIG. 3B, according to one embodiment of the disclosure.

FIGS. 7A-B illustrate single NDR device based memory bit-cells with n-type transistors, according to one embodiment of the disclosure.

FIGS. 8A-B illustrate single NDR device based memory bit-cells with p-type transistors, according to one embodiment of the disclosure.

FIG. 9 illustrates a single NDR device based memory bit-cell with a transistor paired with an NDR device to form a latching element, according to one embodiment of the disclosure.

FIG. 10 illustrates an NDR device based memory bit-cell with TFET transistors, according to one embodiment of the disclosure.

FIG. 11 is a smart device or a computer system or a SoC (System-on-Chip) with NDR device based memory, according to one embodiment of the disclosure.

### DETAILED DESCRIPTION

Some embodiments describe a memory bit-cell which comprises: a storage node; an access transistor coupled to the storage node; a capacitor having a first terminal coupled to the storage node; and one or more negative differential resistance (NDR) devices coupled to the storage node such that the memory bit-cell is without one of a ground line or a supply line or both. In one embodiment, the one or more NDR devices include one of: an Esaki diode; a resonant tunneling diode; or a tunneling FET (TFET).

Some embodiments use NDR characteristics of Tunneling devices together with the 1T-1C (one transistor, one capacitor) bit-cell to create EDRAM bit-cell sized device but with no requirement for refresh (i.e., like an SRAM bit-cell which does not use refreshing). In one embodiment, the NDR based bit-cell forms a compact circuit and layout that counteracts the leakage off the capacitor of the bit-cell and allows the bit-cell to statically hold its state.

So, compared to EDRAM designs, some embodiments make refresh operations unnecessary, making the bit-cell behave as a static RAM. Further, the ability to statically hold state on the storage node alters the design constraints of the access transistor and capacitor to enable additional scaling of those devices. In one embodiment, the layout of the bit-cell uses a vertical arrangement of NDR devices to save area. In one embodiment, the bit-cell re-uses WL (word-line) and PL (capacitor back plate line) as NDR device current sinks to reduce cell size by reducing overall metal routings in the bit-cell. Other technical effects will be evident from the various embodiments described.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

Throughout the specification, and in the claims, the term “connected” means a direct electrical connection between the things that are connected, without any intermediary devices. The term “coupled” means either a direct electrical connection between the things that are connected or an indirect connection through one or more passive or active intermediary devices. The term “circuit” means one or more passive and/or active components that are arranged to cooperate with one another to provide a desired function. The term “signal” means at least one current signal, voltage signal or data/clock signal. The meaning of “a,” “an,” and “the” include plural references. The meaning of “in” includes “in” and “on.”

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level. The terms “substantially,” “close,” “approximately,” “near,” and “about,” generally refer to being within +/−20% of a target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For purposes of the embodiments, the transistors are metal oxide semiconductor (MOS) transistors, which include drain, source, gate, and bulk terminals. The transistors also include Tri-Gate and FinFET transistors, Gate All Around Cylindrical Transistors, Tunneling FET (TFET), Square Wire, or Rectangular Ribbon Transistors or other devices implementing transistor functionality like carbon nano tubes or spintronic devices. MOSFET symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors—BJT PNP/NPN, BiCMOS, CMOS, eFET, etc., may be used without departing from the scope of the disclosure. The term “MN” indicates an n-type transistor (e.g., NMOS, NPN BJT, etc.) and the term “MP” indicates a p-type transistor (e.g., PMOS, PNP BJT, etc.).

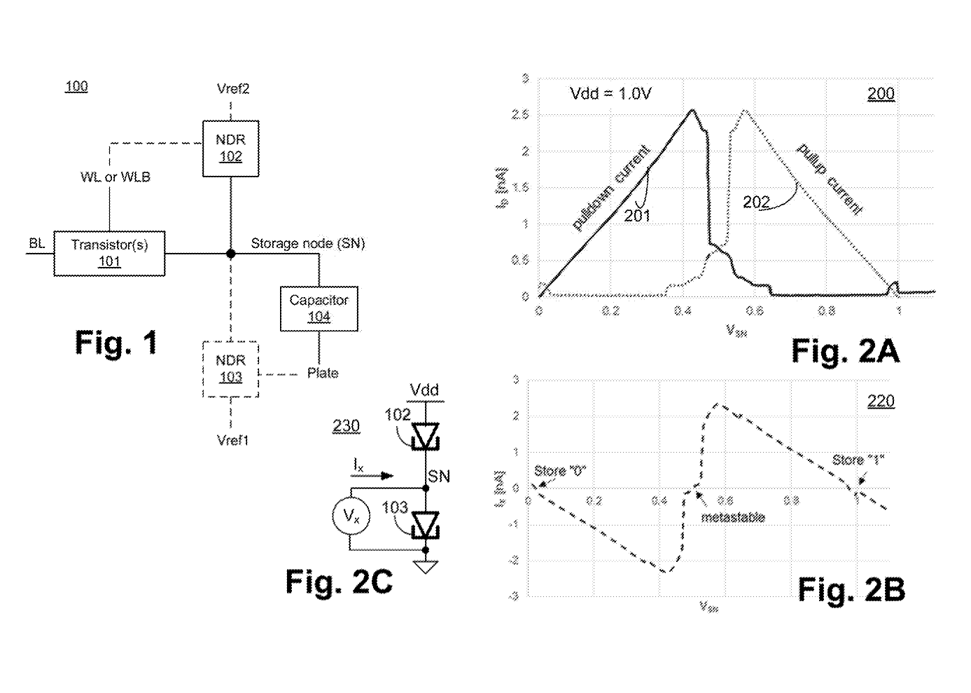

FIG. 1 illustrates a high-level circuit 100 of an NDR device based memory bit-cell, according to one embodiment of the disclosure. In one embodiment, circuit 100 comprises one or more Transistors 101, one or more NDR devices 102 and 103, Storage node (SN), and Capacitor 104. Here, the dotted box for NDR device 103 and the dotted lines indicate optional devices and connection lines. However, other options are also possible as described with reference to various embodiments.

A device with NDR characteristic exhibits higher conductance at low voltages than at high voltages. A variety of materials and device structures exhibit an NDR characteristic including: Esaki diodes, resonant tunneling diodes, and TFETs. The ratio of the maximum current at low voltage to the minimum current at higher voltage is called the peak-to-valley ratio (PVR); and the voltages at which these current levels are observed are known as the peak voltage and valley voltage, respectively. NDR devices have a general limitation of low peak-to-valley ratios and low peak currents. The bit-cells of some embodiments described here work with the low peak currents (e.g., less than 0.1 nA). The bit-cells would work with NDR devices with higher peak current levels as well.

When the two tunneling NDR devices 102 and 103 are coupled in series, the resulting combination is a circuit element called a twin. The twin forms a bi-stable memory element with the middle node as SN. In one embodiment, NDR device 102 is coupled to a reference supply Vref2 and SN. In one embodiment, Vref2 is replaced with WL (word-line) or WLB (inverse of word line). In one embodiment, NDR device 103 is coupled to another reference supply Vref1 and SN. In one embodiment, Vref1 is replaced with Plate (which is a DC bias for basing one of the terminals of Capacitor 104). In one embodiment, when voltage on SN is at a high voltage (e.g., close to Vdd), NDR device 102 (also called the pull-up NDR device) sources current more strongly than the NDR device 103 (also called the pull-down NDR device) can sink it, thus keeping the voltage on SN high. Conversely, when the voltage on SN is at a low voltage pull-down NDR device 103 sinks current more strongly and SN can be held at a low voltage.

Here, NDR devices 102 and 103 are represented as two terminal devices but in general devices 102 and 103 may have two or more physical terminals with an NDR characteristic between at least two terminals. For example, a TFET may show NDR characteristics between source and drain terminals when the TFET gate terminal has a separate biasing voltage.

In one embodiment, the one or more Transistors 101 (also referred here as the access transistor(s)) is a single n-type or p-type transistor. In one embodiment, a combination of TFETs may be used for the one or more Transistors 101. In one embodiment, gate terminal of the one or more Transistors 101 is coupled to WL or WLB depending on whether Transistor 101 is an n-type transistor or a p-type transistor. In one embodiment, source or drain terminal of Transistor 101 is coupled to BL (bit-line) while the drain or source terminal of Transistor 101 is coupled to SN. In one embodiment, SN is coupled to Capacitor 104 such that a first terminal of Capacitor 104 is coupled to SN and a second terminal of Capacitor 104 is coupled to Plate. In one embodiment, the voltage on the Plate is Vdd/2 (i.e., half of the power supply voltage). In other embodiments, the Plate can be biased at different voltage levels.

The twin cell (i.e., NDR devices 102 and 103) helps to hold memory state on capacitive SN. Current driving capability of NDR twin is low (as shown in FIGS. 2A-B), but sufficient to overcome leakage that gradually drains charge off Capacitor 104. In one embodiment, current from NDR device (i.e., one of NDR devices 102 or 103) mitigates the loss of charge from leakage on SN and can restore the stored charge on SN to the original value.

FIGS. 2A-C illustrate plots 200 and 220 and associated circuit 230 showing I-V characteristics of an NDR diode. It is pointed out that those elements of FIGS. 2A-B having the same reference numbers (or names) as the elements of any other figure can operate or function in any manner similar to that described, but are not limited to such.

For FIG. 2A, x-axis is voltage in volts on SN (i.e., V_{SN}), and y-axis is current in nA through the NDR device (i.e., 102 and 103). For FIG. 2B, x-axis is voltage on in volts on SN (i.e., V_{SN}), and y-axis is current Ix in nA into SN. Plots 200 and 220 are formed using circuit 230 of FIG. 2C, in which NDR devices 102 and 103 are replaced with Esaki diodes. Here, Vref2 is Vdd (power supply) while Vref1 is ground (V_{SS}). Voltage source V_{X} is used to drive or sink current to or from SN.

Referring back to FIG. 2A, when V_{SN} increases from 0V, pull down current 201 (i.e., current from SN to ground through NDR device 103) increases while pull up current 202 (i.e., current from SN to Vdd through NDR device 102) remains zero or close to zero until near 0.5V V_{SN}. Near 0.5V on SN, pull down current 201 suddenly falls close to zero while pull up current 202 suddenly rises. As V_{SN} further increases, pull up current 202 declines and reaches near zero as V_{SN} approaches near equal to Vdd, while pull down current 201 remains substantially near to zero and equal to current 202. The region near V_{SN} of 0.5V is a meta-stable region as shown in FIG. 2B.

In FIG. 2B, plot 220 shows the current Iₓ when SN stores a ‘0’ and when SN stores a ‘1’. When V_{SN} is at a high voltage, NDR device 102 sources current more strongly than the NDR device 103 can sink it, thus keeping the voltage on SN high. Conversely, when V_{SN} is at a low voltage pull-down NDR device 103 sinks current more strongly and SN can be held at a low voltage.

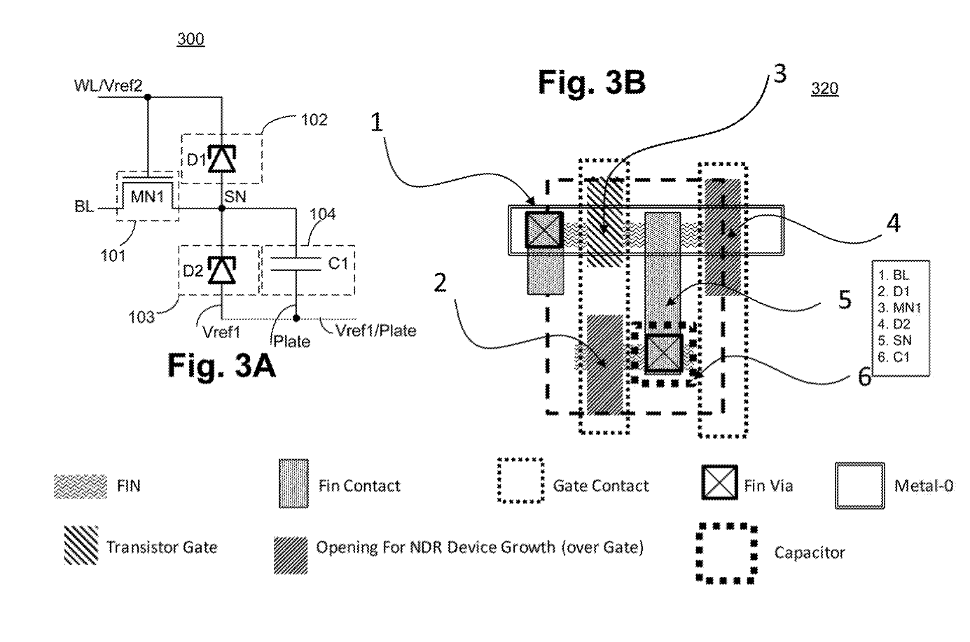

FIG. 3A illustrates NDR device based memory bit-cell 300 with n-type transistor, according to one embodiment of the disclosure. It is pointed out that those elements of FIG. 3A having the same reference numbers (or names) as the elements of any other figure can operate or function in any manner similar to that described, but are not limited to such. While the embodiments here are described with reference to Esaki diodes for NDR devices, other type of NDR devices may be used without departing from the scope of the embodiments.

In this embodiment, one or more Transistors 101 are illustrated by an n-type MOS transistor (MN1) 101, NDR device 102 is illustrated by an Esaki diode D1, and NDR device 103 is illustrated by an Esaki diode D2. In one embodiment, Capacitor C1 104 is a metal capacitor formed above the substrate. In one embodiment, Capacitor C1 104 is a MOS based capacitor formed by a transistor in the substrate. In one embodiment, Capacitor C1 104 is a hybrid capacitor formed from transistor(s) and a metal mesh. In one embodiment, one of the terminals (here, the cathode) of D1 is coupled to WL or Vref2 such that the same metal line is used for controlling the gate terminal of MN1. One technical effect of such an embodiment is that the number of interconnect routings in the bit-cell is reduced, which frees up area for other interconnect routings.

In this embodiment, WL and/or the capacitor back Plate signal is reused to supply the NDR twin (i.e., NDR devices 102 and 103). In such an embodiment, additional routings of Vdd (power supply) and V_{SS} (ground) to each bit-cell is reduced because they are no longer used by bit-cell 300. By reducing the metal routes, size of the bit-cell, and thus the memory array, is reduced because metal routing space, and additional contacts and vias for providing Vdd and V_{SS} are reduced. In one embodiment, since WL is generally at a zero or negative bias it is used to substitute for ground. While the NDR twin may cease to hold state when WL is asserted, this is not problematic because WL assertion occurs transiently when bit-cell 300 is read/written and the charge on SN is restored to the full value at that time. Switching the WL may introduce parasitic currents that discharge Capacitor 104 and parasitic capacitors, but these currents are small compared to those of access transistor MN1. In one embodiment, the positive supply of the NDR twin may be connected to the back Plate of Capacitor 104 when the Plate is held at a logic-1 voltage.

In one embodiment, NDR supply voltage is combined with an addressing line (e.g., word-line, bit-line) or a plate line (i.e., Plate) because the latching behavior from the NDR device is needed to overcome leakage. In such an embodiment, while the NDR device may cease to form a latching element when the addressing lines are used, memory state may be maintained dynamically. At this time in the operation, the low current of the NDR devices is beneficial by preventing a read disturb (e.g., bit-cell erasure). One technical effect of this behavior is a reduction in bit-cell area.

Some non-limiting technical effects of bit-cell 300 are that using NDR devices 102 and 103 in conjunction with storage Capacitor 104, eliminates the need for refresh operations, which saves energy and increases memory array bandwidth. Additionally, the leakage-canceling NDR device enables further scaling of bit-cell 300. For example, Capacitor 104 can be made smaller or leakier without hurting worst-case read margins. Additionally, it is possible to budget for increased leakage through the access transistor MN1. This enables device scaling or the elimination of tightly regulated WL over-/under-drive voltages.

FIG. 3B illustrates a top view of layout 320 of NDR device based memory bit-cell 300 with n-type transistor, according to one embodiment of the disclosure. It is pointed out that those elements of FIG. 3B having the same reference numbers (or names) as the elements of any other figure can operate or function in any manner similar to that described, but are not limited to such.

The bit-cell layout 320 is self explanatory and shows BL, NDR Device 102, access transistor MN1, NDR Device 103, SN, Capacitor C1 104, and associated contacts including contact to gate terminal of MN1, transistor (i.e., FIN) contact, Fin Via, gate region of MN1, opening region for NDR device growth over gate region of MN1, metal capacitor region above the substrate, and Metal-0. By eliminating routing for ground and power supply, ground and power supply contact and vias are removed which make bit-cell layout 320 compact.

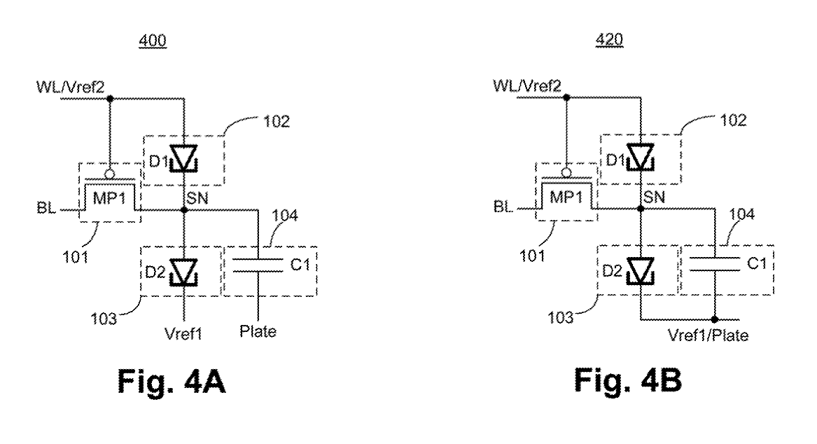

FIGS. 4A-B illustrates NDR device based memory bit-cells 400 and 420 with p-type transistors according to one embodiment of the disclosure. It is pointed out that those elements of FIGS. 4A-B having the same reference numbers (or names) as the elements of any other figure can operate or function in any manner similar to that described, but are not limited to such. So as not to obscure the embodiments of FIGS. 4A-B, differences between the embodiments of FIG. 3A and the embodiments of FIGS. 4A-B are discussed.

The embodiments of FIGS. 4A-B are similar to the embodiments of FIG. 3A, but using p-type MOS transistor instead of an n-type MOS transistor. Functionally, bit-cells 400 and 420 operate similarly to bit-cell 300. In these embodiments, the coupling of the terminals of NDR devices D1 and D2 are also reversed. For example, in the embodiment of bit-cell 400, the anode of NDR device D1 is coupled to WL or Vref2 and the cathode of NDR device D1 is coupled to SN. Likewise, the anode of NDR device D2 is coupled to SN and the cathode of NDR device D2 is coupled to Vref1 or Plate. In the embodiment of FIG. 4B, further number of metal routings, contacts, and vias are reduced by coupling the cathode of the NDR device D2 with Vref1 or Plate. The reversal of the anode and cathode connections is done to match the value of the de-asserted word-line voltage with the value needed to bias the NDR devices in a voltage region where NDR characteristics occur.

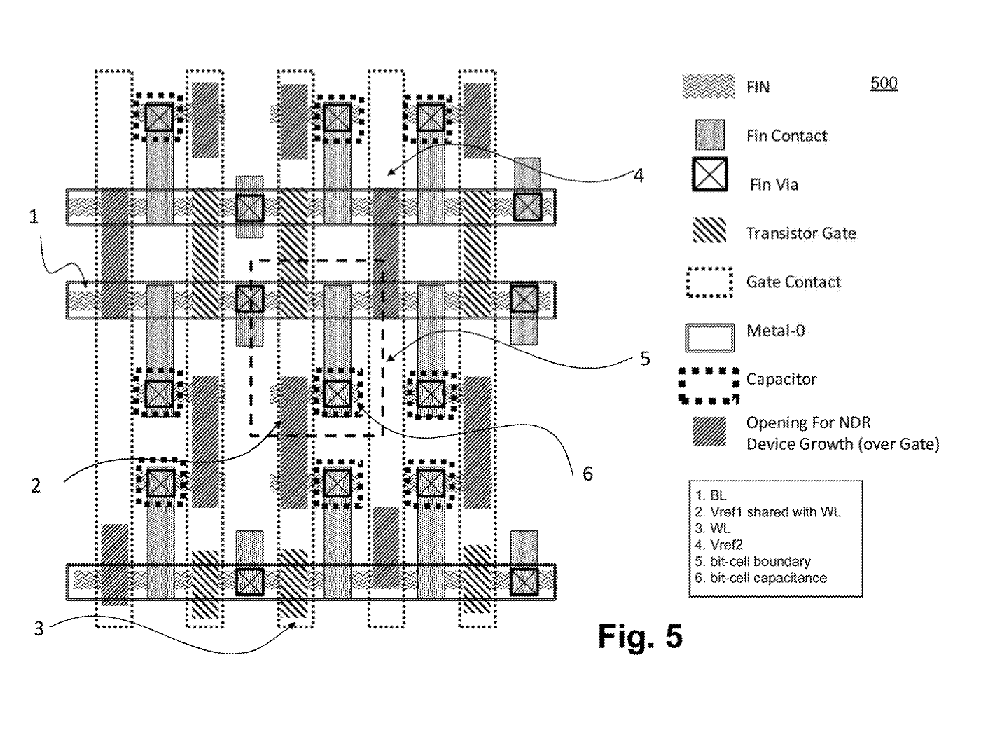

FIG. 5 illustrates a top view of a layout 500 of the NDR device based memory bit-cell array of FIG. 3B, according to one embodiment of the disclosure. It is pointed out that those elements of FIG. 5 having the same reference numbers (or names) as the elements of any other figure can operate or function in any manner similar to that described, but are not limited to such.

Layout 500 shows several bit-cells each having a layout similar to the layout 320 of FIG. 3B. The embodiment of layout 500 shows that by reusing WL for Vref1, metal routing (and associated capacitance and area) is reduced. Layout 500 shows BL (1), WL (2) which is shared with Vref1, WL (3), Vref2 (4), bit-cell boundary (5) of bit-cell 300, and boundary of Capacitor 104 of bit-cell 300 (6). Various layers and regions of array 500 are shown including: FIN (i.e., access transistor 101), Fin Contact, Transistor MN1 gate, Transistor MN1 gate contact, Metal-0 layer, Capacitor 105 boundary, and opening for NDR devices that are formed over the gate terminal of Transistor MN1. The embodiment of layout 500 shows how an array of bit-cells 300 can be positioned for making a compact memory array.

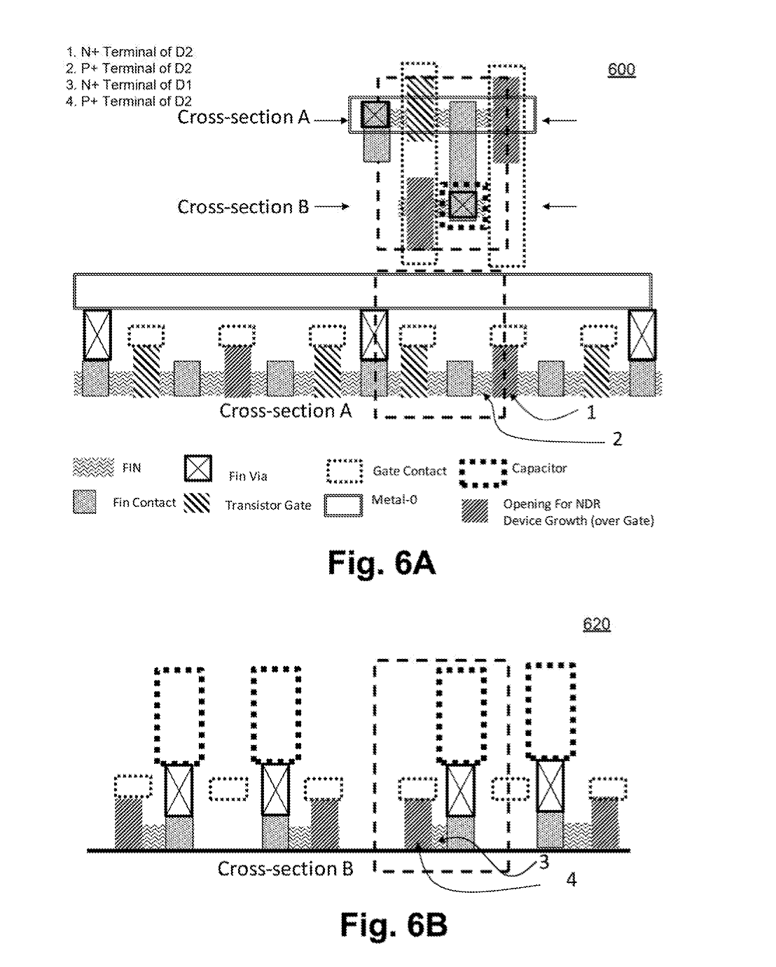

FIG. 6A illustrates a Cross-section A 600 of the layout of the NDR device based memory bit-cell layout 320 of FIG. 3B, according to one embodiment of the disclosure. It is pointed out that those elements of FIG. 6A having the same reference numbers (or names) as the elements of any other figure can operate or function in any manner similar to that described, but are not limited to such. In this embodiment, the bit-line contact, access transistor, SN contact, and NDR device are fit into a dimension equal to 1.5 times the contacted gate pitch. In this embodiment, the benefit of sharing bit-cell addressing and biasing signals is apparent due to the limited extra space for additional wires and contacts.

FIG. 6B illustrates a Cross-section B 620 of the layout of the NDR device based memory bit-cell of FIG. 3B, according to one embodiment of the disclosure. It is pointed out that those elements of FIG. 6B having the same reference numbers (or names) as the elements of any other figure can operate or function in any manner similar to that described, but are not limited to such. In this embodiment, the benefit of sharing bit-cell addressing and biasing signals is apparent due to the limited extra space for additional wires and contacts.

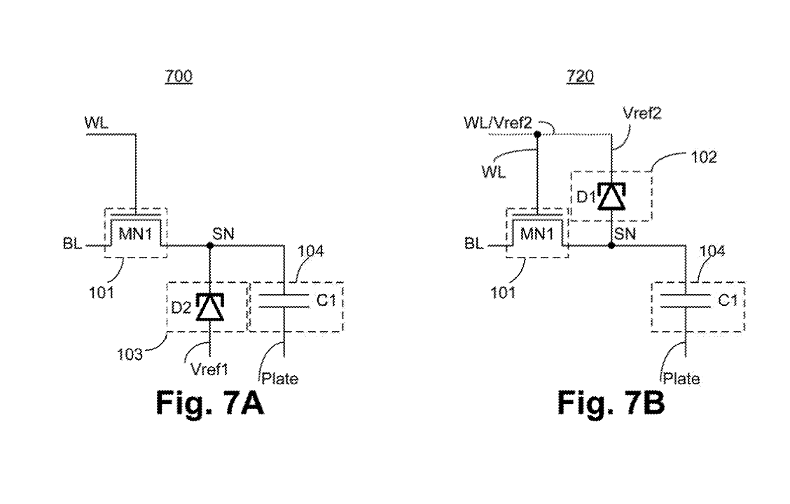

FIGS. 7A-B illustrate single NDR device based memory bit-cells 700 and 720 with n-type transistors MN1, according to one embodiment of the disclosure. It is pointed out that those elements of FIGS. 7A-B having the same reference numbers (or names) as the elements of any other figure can operate or function in any manner similar to that described, but are not limited to such.

In one embodiment, to save additional area compared to bit-cell 300, a single NDR device diode D2 is used as shown in bit-cell 700. In this embodiment, NDR device 102 is eliminated which frees up more area and makes the bit-cell layout compact. In this embodiment, the anode of NDR device D2 is coupled to Vref1 and the cathode of NDR device D2 is coupled to SN. In another embodiment, to save additional area compared to bit-cell 300, a single NDR device diode D1 is used as shown in bit-cell 720. In this embodiment, NDR device 103 is eliminated which frees up more area and makes the bit-cell layout compact. In this embodiment, the cathode of NDR device D1 is coupled to Vref2/WL (i.e., either WL or Vref2) and the anode of NDR device D1 is coupled to SN.

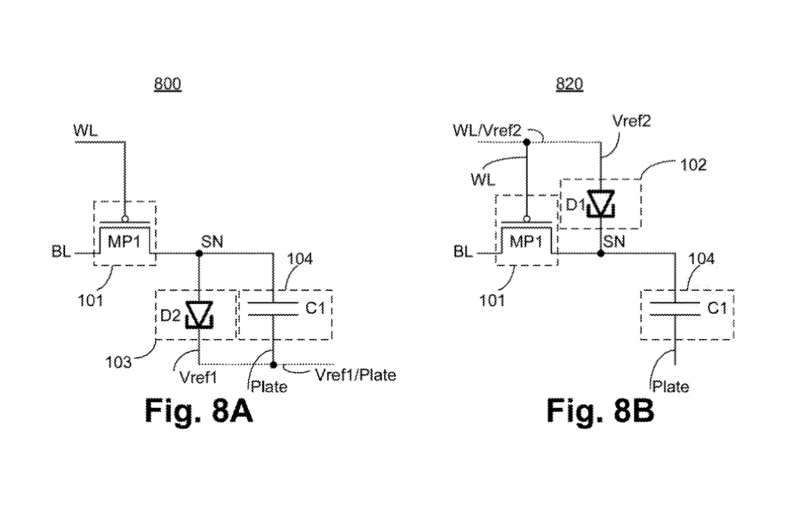

FIGS. 8A-B illustrate single NDR device based memory bit-cells 800 and 820 with p-type transistors MP1, according to one embodiment of the disclosure. It is pointed out that those elements of FIGS. 8A-B having the same reference numbers (or names) as the elements of any other figure can operate or function in any manner similar to that described, but are not limited to such.

In one embodiment, to save additional area compared to bit-cell 400, a single NDR device diode D2 is used as shown in bit-cell 800. In this embodiment, NDR device 102 is eliminated which frees up more area and makes the bit-cell layout compact. In this embodiment, the cathode of D2 is coupled to Vref1 (or Plate) and the anode of D2 is coupled to SN. In another embodiment, to save additional area compared to bit-cell 420, a single NDR device diode D1 is used as shown in bit-cell 820. In this embodiment, NDR device 103 is eliminated which frees up more area and makes the layout of bit-cell 820 compact. In this embodiment, the anode of NDR device D1 is coupled to Vref2/WL (i.e., either WL or Vref2) and the cathode of NDR device D1 is coupled to SN.

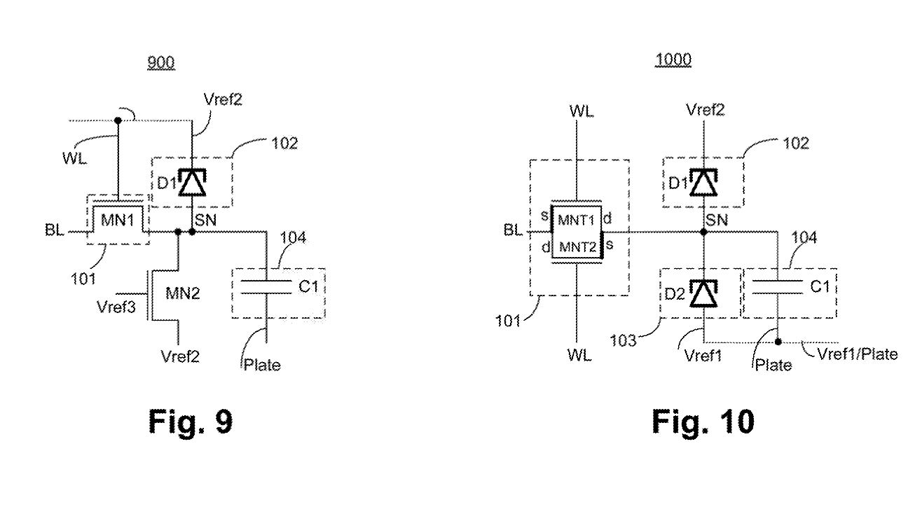

FIG. 9 illustrates a single NDR device based memory bit-cell 900 with a transistor paired with an NDR device to form a latching element, according to one embodiment of the disclosure. It is pointed out that those elements of FIG. 9 having the same reference numbers (or names) as the elements of any other figure can operate or function in any manner similar to that described, but are not limited to such.

In this embodiment, compared to bit-cell 300, NDR device 103 is replaced with a transistor leakage path. Here, that path is shown by n-type transistor MN2. In one embodiment, gate terminal of MN2 is coupled to Vref3, source terminal of MN2 is coupled to Vref2, and drain terminal of MN2 is coupled to SN. In this embodiment, MN2 provides the load that causes state retention in conjunction with using a single NDR device (here, device 102). In one embodiment, layout density for bit-cell 900 is improved over layout 320 because transistor MN2 has less process complexity than NDR device 103. In one embodiment, bias voltage Vref2 can be shared with Plate.

FIG. 10 illustrates an NDR device based memory bit-cell 1000 with TFET transistors, according to one embodiment of the disclosure. It is pointed out that those elements of FIG. 10 having the same reference numbers (or names) as the elements of any other figure can operate or function in any manner similar to that described, but are not limited to such.

TFETs are promising devices in that they may provide significant performance increase and energy consumption decrease due to a steeper sub-threshold slope. In this embodiment, one or more Transistors 101 are replaced with two n-type TFETs MNT1 and MNT2. In this embodiment, since TFETs channel current is asymmetric (i.e., the current flows substantially in one direction), source terminal of MNT1 is coupled to drain terminal of MNT2, and drain terminal of MNT1 is coupled to source terminal of MNT2.

The other elements and devices of bit-cell 1000 are the same as those described with reference to FIG. 3. Other alternatives of bit-cell 1000 can be any of the alternative designs discussed with reference to other embodiments but using TFETs MNT1 and MNT2 instead of transistor MN1. A similar bit-cell 1000 can be formed using p-type TFETs MPT1 and MPT2 (not shown) with similar topology of NDR device(s) as shown with reference to other embodiments of p-type transistor based memory bit-cells. Using TFET's may improve the low voltage performance of the bit-cell or provide for an easier integration of devices with NDR characteristics.

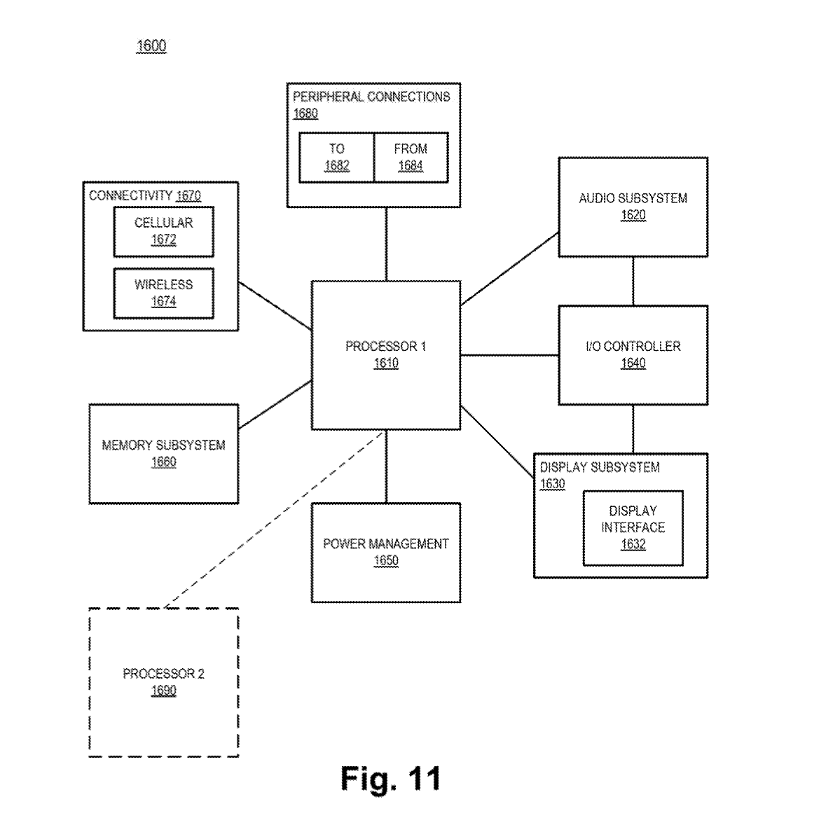

FIG. 11 is a smart device or a computer system or a SoC (System-on-Chip) with NDR device based memory, according to one embodiment of the disclosure. It is pointed out that those elements of FIG. 11 having the same reference numbers (or names) as the elements of any other figure can operate or function in any manner similar to that described, but are not limited to such.

FIG. 11 illustrates a block diagram of an embodiment of a mobile device in which flat surface interface connectors could be used. In one embodiment, computing device 1600 represents a mobile computing device, such as a computing tablet, a mobile phone or smart-phone, a wireless-enabled e-reader, or other wireless mobile device. It will be understood that certain components are shown generally, and not all components of such a device are shown in computing device 1600.

In one embodiment, computing device 1600 includes a first processor 1610 with NDR device based memory, according to the embodiments discussed. Other blocks of the computing device 1600 may also include the apparatus of NDR device based memory of the embodiments. The various embodiments of the present disclosure may also comprise a network interface within 1670 such as a wireless interface so that a system embodiment may be incorporated into a wireless device, for example, cell phone or personal digital assistant.

In one embodiment, processor 1610 (and/or processor 1690) can include one or more physical devices, such as microprocessors, application processors, microcontrollers, programmable logic devices, or other processing means. The processing operations performed by processor 1610 include the execution of an operating platform or operating system on which applications and/or device functions are executed. The processing operations include operations related to I/O (input/output) with a human user or with other devices, operations related to power management, and/or operations related to connecting the computing device 1600 to another device. The processing operations may also include operations related to audio I/O and/or display I/O.

In one embodiment, computing device 1600 includes audio subsystem 1620, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 1600, or connected to the computing device 1600. In one embodiment, a user interacts with the computing device 1600 by providing audio commands that are received and processed by processor 1610.

Display subsystem 1630 represents hardware (e.g., display devices) and software (e.g., drivers) components that provide a visual and/or tactile display for a user to interact with the computing device 1600. Display subsystem 1630 includes display interface 1632, which includes the particular screen or hardware device used to provide a display to a user. In one embodiment, display interface 1632 includes logic separate from processor 1610 to perform at least some processing related to the display. In one embodiment, display subsystem 1630 includes a touch screen (or touch pad) device that provides both output and input to a user.

I/O controller 1640 represents hardware devices and software components related to interaction with a user. I/O controller 1640 is operable to manage hardware that is part of audio subsystem 1620 and/or display subsystem 1630. Additionally, I/O controller 1640 illustrates a connection point for additional devices that connect to computing device 1600 through which a user might interact with the system. For example, devices that can be attached to the computing device 1600 might include microphone devices, speaker or stereo systems, video systems or other display devices, keyboard or keypad devices, or other I/O devices for use with specific applications such as card readers or other devices.

As mentioned above, I/O controller 1640 can interact with audio subsystem 1620 and/or display subsystem 1630. For example, input through a microphone or other audio device can provide input or commands for one or more applications or functions of the computing device 1600. Additionally, audio output can be provided instead of, or in addition to display output. In another example, if display subsystem 1630 includes a touch screen, the display device also acts as an input device, which can be at least partially managed by I/O controller 1640. There can also be additional buttons or switches on the computing device 1600 to provide I/O functions managed by I/O controller 1640.

In one embodiment, I/O controller 1640 manages devices such as accelerometers, cameras, light sensors or other environmental sensors, or other hardware that can be included in the computing device 1600. The input can be part of direct user interaction, as well as providing environmental input to the system to influence its operations (such as filtering for noise, adjusting displays for brightness detection, applying a flash for a camera, or other features).

In one embodiment, computing device 1600 includes power management 1650 that manages battery power usage, charging of the battery, and features related to power saving operation. Memory subsystem 1660 includes memory devices for storing information in computing device 1600. Memory can include nonvolatile (state does not change if power to the memory device is interrupted) and/or volatile (state is indeterminate if power to the memory device is interrupted) memory devices. Memory subsystem 1660 can store application data, user data, music, photos, documents, or other data, as well as system data (whether long-term or temporary) related to the execution of the applications and functions of the computing device 1600.

Elements of embodiments are also provided as a machine-readable medium (e.g., memory 1660) for storing the computer-executable instructions (e.g., instructions to implement any other processes discussed herein). The machine-readable medium (e.g., memory 1660) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity 1670 includes hardware devices (e.g., wireless and/or wired connectors and communication hardware) and software components (e.g., drivers, protocol stacks) to enable the computing device 1600 to communicate with external devices. The computing device 1600 could be separate devices, such as other computing devices, wireless access points or base stations, as well as peripherals such as headsets, printers, or other devices.

Connectivity 1670 can include multiple different types of connectivity. To generalize, the computing device 1600 is illustrated with cellular connectivity 1672 and wireless connectivity 1674. Cellular connectivity 1672 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 1674 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 1680 include hardware interfaces and connectors, as well as software components (e.g., drivers, protocol stacks) to make peripheral connections. It will be understood that the computing device 1600 could both be a peripheral device (“to” 1682) to other computing devices, as well as have peripheral devices (“from” 1684) connected to it. The computing device 1600 commonly has a “docking” connector to connect to other computing devices for purposes such as managing (e.g., downloading and/or uploading, changing, synchronizing) content on computing device 1600. Additionally, a docking connector can allow computing device 1600 to connect to certain peripherals that allow the computing device 1600 to control content output, for example, to audiovisual or other systems.

In addition to a proprietary docking connector or other proprietary connection hardware, the computing device 1600 can make peripheral connections 1680 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. For example, other memory architectures e.g., Dynamic RAM (DRAM) may use the embodiments discussed. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

For example, a memory bit-cell is provided which comprises: a storage node; an access transistor coupled to the storage node; a capacitor having a first terminal coupled to the storage node; and one or more negative differential resistance devices coupled to the storage node such that the memory bit-cell is without one of a ground line or a supply line or both. In one embodiment, the one or more negative differential resistance devices includes one of: an Esaki diode; a resonant tunneling diode; or a tunneling FET (TFET).

In one embodiment, the access transistor has a gate terminal coupled to a word-line. In one embodiment, the one or more negative differential resistance devices is a single device having a first terminal coupled to the word-line, and a second terminal coupled to the storage node. In one embodiment, the one or more negative differential resistance devices comprise: a first negative differential resistance device having a first terminal coupled to the word-line, and second terminal coupled to the storage node; and a second negative differential resistance device having a first terminal coupled to the storage node, and a second terminal coupled to a power supply node.

In one embodiment, the one or more negative differential resistance devices comprise: a first negative differential resistance device having a first terminal coupled to the word-line, and a second terminal coupled to the storage node; and a second negative differential resistance device having a first terminal coupled to the storage node, and a second terminal coupled to a second terminal of the capacitor. In one embodiment, the access transistor is coupled to a bit-line.

In one embodiment, the access transistor is one of: a p-type transistor; or an n-type transistor. In one embodiment, the capacitor is formed as one of: a transistor based capacitor; a metal capacitor; or a combination of a metal capacitor and a transistor based capacitor. In one embodiment, the access transistor comprises a first TFET and a second TFET. In one embodiment, a source terminal of the first TFET is coupled to a drain terminal of the second TFET, and wherein a drain terminal of the first TFET 15 coupled to a source terminal of the second TFET.

In one embodiment, the one or more negative differential resistance devices is a single negative differential resistance device, and wherein the memory bit-cell further comprises a transistor, separate from the access transistor, coupled to the storage node. In one embodiment, a gate terminal of the transistor is to be biased by a reference voltage.

In another example, a system is provided which comprises: a processor having a memory array formed from memory bit-cells organized in rows and columns, wherein each memory bit-cell is according to the memory bit-cell described above; and a wireless interface for allowing the processor to communicate with another device. In one embodiment, the system further comprises a memory die stacked over or under the processor.

In another example, a bit-cell is provided which comprises: a word-line; a bit-line; a storage node; an access transistor coupled to the storage node, word-line, and bit-line; a capacitor having a first terminal coupled to the storage node and a second terminal coupled to a voltage node; and a first negative differential resistance device coupled to the storage node and the word-line. In one embodiment, the bit-cell further comprises a second negative differential resistance device coupled to the storage node and the voltage node.

In one embodiment, the first and second negative differential resistance devices include one of: an Esaki diode; a resonant tunneling diode; or a tunneling FET (TFET). In one embodiment, the access transistor is one of: a p-type transistor; or an n-type transistor. In one embodiment, the voltage node is coupled to a supply which is half of a nominal power supply. In one embodiment, the bit-cell further comprises a transistor, separate from the access transistor, coupled to the storage node, wherein a gate terminal of the transistor is to be biased by a reference voltage.

In another example, a system is provided which comprises: a processor having a memory array formed from bit-cells organized in rows and columns, wherein each bit-cell is according to the bit-cell described above; and a wireless interface for allowing the processor to communicate with another device. In one embodiment, the system further comprises a memory die stacked over or under the processor.

In another example, a memory bit-cell is provided which comprises: a storage node; an access transistor coupled to the storage node; a capacitor having a first terminal coupled to the storage node; and one or more negative differential resistance devices coupled to the storage node such that at least one negative differential resistance device is also coupled to a word-line, bit-line, plate-line or other addressing signal.

In one embodiment, the one or more negative differential resistance devices comprise: a first negative differential resistance device having a first terminal coupled to the bit-line, and second terminal coupled to the storage node; and a second negative differential resistance devices having a first terminal coupled to the storage node, and a second terminal coupled to another signal.

In another example, a method is provided which comprises: coupling an access transistor coupled to a storage node; coupling a capacitor having a first terminal to the storage node; and coupling one or more negative differential resistance devices to the storage node such that the memory bit-cell is without one of a ground line or a supply line or both. In one embodiment, the one or more negative differential resistance devices includes one of: an Esaki diode; a resonant tunneling diode; or a tunneling FET (TFET).

In one embodiment, the method further comprises coupling a gate terminal of the access transistor to a word-line. In one embodiment, the one or more negative differential resistance devices is a single device having first and second terminals, and wherein the method further comprises: coupling the first terminal to the word-line, and coupling the second terminal to the storage node.

In one embodiment, the one or more negative differential resistance devices comprise: a first negative differential resistance device having first and second terminals; and a second negative differential resistance device has first and second terminals. In one embodiment, the method further comprises: coupling the first terminal of the first negative differential resistance device to the word-line; and coupling the second terminal of the first negative differential resistance device to the storage node.

In one embodiment, the method further comprises: coupling the first terminal of the second negative differential resistance device to the storage node; and coupling the second terminal of the second negative differential resistance device to a power supply node. In one embodiment, the method further comprises: coupling the first terminal of the second negative differential resistance device to the storage node; and coupling the second terminal of the second negative differential resistance device to a second terminal of the capacitor.

In one embodiment, the method further comprises coupling the access transistor to a bit-line. In one embodiment, the access transistor is one of: a p-type transistor; or an n-type transistor. In one embodiment, the method further comprises forming the capacitor as one of: a transistor based capacitor; a metal capacitor; or a combination of a metal capacitor and a transistor based capacitor. In one embodiment, the access transistor comprises a first TFET and a second TFET.

In one embodiment, the method further comprises: coupling a source terminal of the first TFET to a drain terminal of the second TFET, and coupling a drain terminal of the first TFET to a source terminal of the second TFET. In one embodiment, the one or more negative differential resistance devices is a single negative differential resistance device, and wherein the method further comprises coupling a transistor, separate from the access transistor, to the storage node. In one embodiment, the method further comprises biasing a gate terminal of the transistor by a reference voltage.

In another example, an apparatus is provided which comprises: means for coupling an access transistor coupled to a storage node; means for coupling a capacitor having a first terminal to the storage node; and means for coupling one or more negative differential resistance devices to the storage node such that the memory bit-cell is without one of a ground line or a supply line or both. In one embodiment, the one or more negative differential resistance devices includes one of: an Esaki diode; a resonant tunneling diode; or a tunneling FET (TFET).

In one embodiment, the apparatus further comprises means for coupling a gate terminal of the access transistor to a word-line. In one embodiment, the one or more negative differential resistance devices is a single device having first and second terminals, and wherein the method further comprises: means for coupling the first terminal to the word-line, and means for coupling the second terminal to the storage node. In one embodiment, the one or more negative differential resistance devices comprise: a first negative differential resistance device having first and second terminals; and a second negative differential resistance device has first and second terminals.

In one embodiment, the method further comprises: means for coupling the first terminal of the first negative differential resistance device to the word-line; and means for coupling the second terminal of the first negative differential resistance device to the storage node. In one embodiment, the method further comprises: means for coupling the first terminal of the second negative differential resistance device to the storage node; and means for coupling the second terminal of the second negative differential resistance device to a power supply node.

In one embodiment, the method further comprises: means for coupling the first terminal of the second negative differential resistance device to the storage node; and means for coupling the second terminal of the second negative differential resistance device to a second terminal of the capacitor. In one embodiment, the apparatus further comprises means for coupling the access transistor to a bit-line. In one embodiment, the access transistor is one of: a p-type transistor; or an n-type transistor. In one embodiment, the apparatus further comprises means for forming the capacitor as one of: a transistor based capacitor; a metal capacitor; or a combination of a metal capacitor and a transistor based capacitor.

In one embodiment, the access transistor comprises a first TFET and a second TFET. In one embodiment, the apparatus further comprises: means for coupling a source terminal of the first TFET to a drain terminal of the second TFET, and means for coupling a drain terminal of the first TFET to a source terminal of the second TFET. In one embodiment, the one or more negative differential resistance devices is a single negative differential resistance device, and wherein the method further comprises means for coupling a transistor, separate from the access transistor, to the storage node. In one embodiment, the apparatus further comprises means for biasing a gate terminal of the transistor by a reference voltage.

In another example, a system is provided which comprises: a processor having a memory array formed from memory bit-cells organized in rows and columns, wherein each memory bit-cell is according to any one of claims 41 to 55; and a wireless interface for allowing the processor to communicate with another device. In one embodiment, the system further comprises a memory die stacked over or under the processor.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1-25. (canceled)

26. A memory bit-cell comprising:
a storage node;
an access transistor coupled to the storage node;
a capacitor having a first terminal coupled to the storage node; and
one or more negative differential resistance devices coupled to the storage node such that the memory bit-cell is without one of a ground line or a supply line or both.

27. The memory bit-cell of claim 26, wherein the one or more negative differential resistance devices includes one of:
an Esaki diode;
a resonant tunneling diode; or
a tunneling FET (TFET).

28. The memory bit-cell of claim 26, wherein the access transistor has a gate terminal coupled to a word-line.

29. The memory bit-cell of claim 28, wherein the one or more negative differential resistance devices is a single device having a first terminal coupled to the word-line, and a second terminal coupled to the storage node.

30. The memory bit-cell of claim 28, wherein the one or more negative differential resistance devices comprise:
a first negative differential resistance device having a first terminal coupled to the word-line, and second terminal coupled to the storage node; and
a second negative differential resistance device having a first terminal coupled to the storage node, and a second terminal coupled to a power supply node.

31. The memory bit-cell of claim 28, wherein the one or more negative differential resistance devices comprise:
a first negative differential resistance device having a first terminal coupled to the word-line, and a second terminal coupled to the storage node; and
a second negative differential resistance device having a first terminal coupled to the storage node, and a second terminal coupled to a second terminal of the capacitor.

32. The memory bit-cell of claim 26, wherein the access transistor is coupled to a bit-line.

33. The memory bit-cell of claim 26, wherein the access transistor is one of: a p-type transistor; or an n-type transistor.

34. The memory bit-cell of claim 26, wherein the capacitor is formed as one of:
a transistor based capacitor;
a metal capacitor; or
a combination of a metal capacitor and a transistor based capacitor.

35. The memory bit-cell of claim 26, wherein the access transistor comprises a first TFET and a second TFET.

36. The memory bit-cell of claim 35, wherein a source terminal of the first TFET 15 coupled to a drain terminal of the second TFET, and wherein a drain terminal of the first TFET is coupled to a source terminal of the second TFET.

37. The memory bit-cell of claim 26, wherein the one or more negative differential resistance devices is a single negative differential resistance device, and wherein the memory bit-cell further comprises a transistor, separate from the access transistor, coupled to the storage node.

38. The memory bit-cell of claim 37, wherein a gate terminal of the transistor is to be biased by a reference voltage.

39. A bit-cell comprising:
a word-line;
a bit-line;
a storage node;
an access transistor coupled to the storage node, word-line, and bit-line;
a capacitor having a first terminal coupled to the storage node and a second terminal coupled to a voltage node; and
a first negative differential resistance device coupled to the storage node and the word-line.

40. The bit-cell of claim 39 further comprises a second negative differential resistance device coupled to the storage node and the voltage node.

41. The bit-cell of claim 40, wherein the first and second negative differential resistance devices include one of:
an Esaki diode;
a resonant tunneling diode; or
a tunneling FET (TFET).

42. The bit-cell of claim 39, wherein the access transistor is one of: a p-type transistor; or an n-type transistor.

43. The bit-cell of claim 39 further comprises a transistor, separate from the access transistor, coupled to the storage node, wherein a gate terminal of the transistor is to be biased by a reference voltage.

44. A system comprising:
a processor having a memory array formed from memory bit-cells organized in rows and columns, wherein each memory bit-cell comprises:
a storage node;
an access transistor coupled to the storage node;
a capacitor having a first terminal coupled to the storage node; and
one or more negative differential resistance devices coupled to the storage node such that the memory bit-cell is without one of a ground line or a supply line or both; and
a wireless interface for allowing the processor to communicate with another device.

45. The system of claim 44 further comprises a memory die stacked over or under the processor.
